(19) United States
(12) Patent Application Publication
(10) Pub. No.: US 2007/0289334 A1
(43) Pub. Date: Dec. 20, 2007

(54) Method For Producing A Photonic Crystal Comprised Of A Material With A High Refractive Index

(76) Inventors: Nicolas Tetreault, Ontario (CA); Georg Ludwig Eberhard Von Freymann, Karlsruhe (DE); Geoffrey A. Ozin, Ontario (CA); Markus Deubel, Schweighofen (DE); Martin Wegener, Karlsruhe (DE)

Correspondence Address: FRIEDRICH KUEFFNER, 317 MADISON AVENUE, SUITE 910, NEW YORK, NY, 10017, US

(21) Appl. No.: 11/659,433

(22) PCT Filed: Aug. 5, 2005
(86) PCT No.: PCT/EP05/54232

§ 371 Date: Sep. 10, 2007

(30) Foreign Application Priority Data
Aug. 5, 2004 (DE) 102004037950.5

(51) Int. Cl. G03F 7/00; C03B 37/016

(52) U.S. Cl. 65/391; 430/2; 65/385; 65/395

(57) ABSTRACT

The invention relates to a process for producing a three-dimensional photonic crystal which consists of a material with high refractive index. To this end, a photonic crystal which consists of a polymer is first provided, through whose surface there are empty interstitial sites. As a result of introduction of a filler into the interstitial sites, a network forms there from the filler. After the removal of the polymer, cavities form in the network formed from the filler, into which the material with high refractive index is introduced, so that a structure of the material with high refractive index forms therein. After the removal of the filler, the structure of the material with high refractive index remains, which can be removed as the photonic crystal which consists of a material with high refractive index. Photonic crystals produced by the process according to the invention have complete band gaps in the region of telecommunications wavelengths.

This application claims the priority of DE 10 2004 037 950.5.

The invention relates to a process for producing a three-dimensional photonic crystal which consists of a material with high refractive index.

Photonic crystals, which date back to E. Yablonovitch, Phys. Rev. Lett., Volume 58, page 2059-2062, 1987, and S. John, ibid., page 2486-2489, 1987, are periodically structured dielectric materials which constitute the optical analog of semiconductor crystals and thus enable the production of integrated photonic circuits.

Extended photonic band gaps, which, according to K.-M. Ho, C. T. Chan, and C. M. Soukoulis, Phys. Rev. Lett. Volume 65, page 3152-3155, 1990, can theoretically have up to 25% of the central frequency of silicon at 2.6 μm, can be produced with photonic crystals which have a diamond structure instead of a face-centered cubic structure.

Layer structures in particular are, according to K.-M. Ho, C. T. Chan, C. M. Soukoulis, R. Biswas, and M. Sigalas,. Solid State Comm., Volume 89, page 413-416, 1994, and E. Özbay et al, Phys. Rev. B, Volume 50, page 1945-1948, 1994, obtainable via microfabrication processes. Recently, S. Y. Lin et al., Nature, Volume 394, page 251-253, 1998, S. Noda et al., Science, Volume 289, page 604-606, 2000, and K. Aoki et al., Nature Materials, Volume 2, page 117-121, 2003, have produced photonic crystals for infrared frequencies by combining planar semiconductor microstructuring processes for individual layers with sophisticated alignment and stacking processes in order to configure a three-dimensional photonic crystal from the layers.

This allows incorporation of functional elements by controlled changes in individual layers. However, stacking had to date only been successful for a few layers, which leads to high coupling between the conduction modes in the photonic crystal and the loss modes in the surrounding material, as a result of which the performance of the functional elements is restricted.

Therefore, M. Campbell et al., Nature, Volume 404, page 53-56, 2000, and Y. V. Miklyaev et al., Appl. Phys. Lett., Volume 82, page 1284-1286, 2003, moved to the production of extended three-dimensional photonic crystals of high quality in photoresist layers by means of holographic lithography. Here, the thickness of the photonic crystals is in principle restricted only by the thickness of the photoresist layer and its absorption. Holographic lithography enables the provision of defect-free layers with a thickness of a few 10s unit cells with an expansion of a few mm², this process having great flexibility with regard to the contents of the unit cell. However, this multibeam interference process only allows the production of strictly periodic structures.

Therefore, a second complementary process is required to write functional elements, for example waveguides or microcavity structures, into the interior of a photonic crystal which has been produced by holographic lithography.

Particularly suitable for this purpose is the so-called direct laser writing (DLW) by multiphoton polymerization in the photosensitive material, known from S. Kawata, H.-B. Sun, T. Tanaka and K. Takada, Nature, Volume 412, page 697-698, 2001.

In this method, a photoresist is illuminated by means of a laser whose frequency is below the single-photon polymerization threshold of the photoresist. When this laser is focused onto the interior of the photoresist, the light intensity within a small volume at the focal point can exceed the threshold for multiphoton polymerization. Size and shape of these so-called voxels depend upon the isointensity surfaces, i.e. isophotes, the microscope lens used and the illumination threshold for multiphoton polymerization in the photosensitive material. Using this process, S. Kawata et al. have to date been able to produce voxels with a size down to 120 nm with illumination at 780 nm.

In conjunction with holographic lithography, direct laser writing offers a rapid and precise way of providing functional elements in photonic crystals. However, the introduction of materials with high refractive index is not possible thereby, since high temperatures for the coating and high chemical reactivity of the precursor substances for known coating processes, for example chemical vapor deposition (CVD), destroy the existing structures.

Proceeding from this, it is an object of the present invention to propose a process for producing a photonic crystal which consists of a material with high refractive index, said process not having the disadvantages and restrictions mentioned.

This object is achieved by the features of claim 1. The subclaims each describe advantageous embodiments of the invention.

The process according to the invention constitutes a double inversion process, i.e. the original polymeric photonic crystal is first converted to a spatially inverse structure which in turn, as a result of a second inversion, forms a photonic crystal which consists of the desired material with high refractive index. The starting materials are in each case removed with suitable processes.

The starting point of the process according to the invention is a three-dimensional photonic crystal which consists of a polymer and is provided according to process step a). To this end, according to the prior art, preference is given to applying a polymer or a polymerizable monomer by means of spin-coating to a first substrate made of glass, silicon or a polymer.

In a particularly embodiment, this polymer or polymerizable monomer covers the entire first substrate and is then, if appropriate, completely polymerized. Only then is a second layer of the polymer or polymerizable monomer applied thereto.

Subsequently, a polymeric photonic crystal with the desired crystal structure is produced from the polymer, preferably by means of holographic lithography, direct laser writing or a combination of the two processes. Such a photonic crystal has a surface area by which a lattice with empty interstitial sites is defined.

The first inversion, i.e. the conversion of the original polymeric photonic crystal to a spatially inverse structure, is effected by, according to process step b), introducing a suitable filler into the empty interstitial sites in such a way that a network is formed from the filler at the interstitial sites.

In a preferred embodiment, a precursor substance of the filler is introduced into the initially empty interstitial sites, where it is deposited onto the surface of the polymeric photonic crystal. The amount of precursor substance is selected such that it fills a predetermined volume fraction of the empty interstitials which is sufficient to form a layer from the filler on the surface of the polymeric photonic crystal, which constitutes an interconnected network of filler in the previously empty interstitial sites of the polymeric photonic crystal.

In a particularly preferred embodiment, silicon tetrachloride SiCl₄ is used as the precursor substance and then converted to the desired silicate filler SiO₂ in a conventional manner.

Since, in process step b), the entire polymer structure present is covered with the filler material, direct removal of the polymer in process step c) by thermal decomposition or plasma etching is generally not possible. Thermal decomposition leads to generation of gaseous products within the closed structure and hence to their explosive decomposition; plasma etching does not work since the reactive gases cannot reach the polymer to be decomposed through the filler material.

In a particular embodiment, this difficulty is circumvented by, before the removal of the polymer, applying a second substrate, which preferably consists of glass or another material which is stable at high temperatures but can be released in strong acids, to the structure, preferably by means of a sol-gel process or an adhesive (high-performance adhesive). In the thermal composition which follows, the gaseous products separate the first substrate from the structure which, in this embodiment, rests on a thin polymer layer. After this separation, sufficient removal channels have been opened for the gaseous decomposition products of the polymer from the interior of the structure, so that they can escape without destroying the structure.

In an alternative embodiment, this difficulty is circumvented by removing the uppermost layer from the filler (silicate) by means of reactive ion etching. This too opens up sufficient removal channels for the gaseous reaction products of the polymer from the interior of the structure, so that they can escape without destroying the structure.

When, in process step c), the polymer of which the original photonic crystal consisted has been removed, preferably by means of plasma etching or thermal decomposition, cavities form in the network formed from filler.

The desired photonic crystal is now produced from the structure thus formed by a second inversion. To this end, in process step d), the selected material with high refractive index, i.e. high dielectric constant, is introduced into the cavities formed beforehand, so that a structure of the material with high refractive index forms therein. The material with high refractive index is preferably applied layer by layer to the inner surfaces of the cavities in the filler up to the desired thickness.

The materials with high refractive index used are preferably the semiconductors silicon, also provided with various n- or p-dopants, germanium or an SiₓGe₁₋ₓ alloy. Silicon may itself be amorphous, nanocrystalline, polycrystalline or monocrystalline, hydrogenated nanocrystalline silicon (nc-Si:H) being a particularly preferred material. In addition, II-V, II-VI, I-VII, IV-VI semiconductors including their n- or p-doped variants, or metals with high refractive index, for example silver (Ag), gold (Au), tungsten (W), iridium (Ir) or tantalum (Ta), are equally suitable.

Before, finally, in process step e), the photonic crystal which consists of the material with high refractive index is removed, once the filler has been removed, the structure, preferably by means of an optically transparent adhesive (optical adhesive), is secured to a third substrate which is inert toward strong acids, for example hydrogen fluoride (HF) or hydrochloric acid (HCl), and preferably consists of a polymer of optical quality. Without this step, there is the risk of losing a photonic crystal with low dimensions in the acid after the removal of the filler material and the substrate.

The removal of the filler, which is preferably effected by means of a strong acid, for example hydrogen fluoride (HF) or hydrochloric acid (HCl), brings about, if appropriate, the removal of the original substrate and the formation of the desired three-dimensional photonic crystal of material with high refractive index, whose structure is similar or identical to the polymeric three-dimensional photonic crystal provided in process step a). The crystal lattice of the photonic crystal thus obtained may, for example, have a cubic face-centered (fcc), a simple cubic (sc), a slanted pore, a diamond or a quadratic spiral structure.

The process according to the invention enables the production of three-dimensional photonic crystals with high dielectric contrast. These may have any structures and topologies which can be produced by means of holographic lithography, direct laser writing or a combination of the two processes. This at the same time allows functional photonic devices based on three-dimensional photonic crystals to be produced without further process steps. Photonic crystals produced by the process according to the invention have complete band gaps in the region of telecommunications wavelengths.

The invention is illustrated hereinafter with reference to working examples and the figures. The figures show:

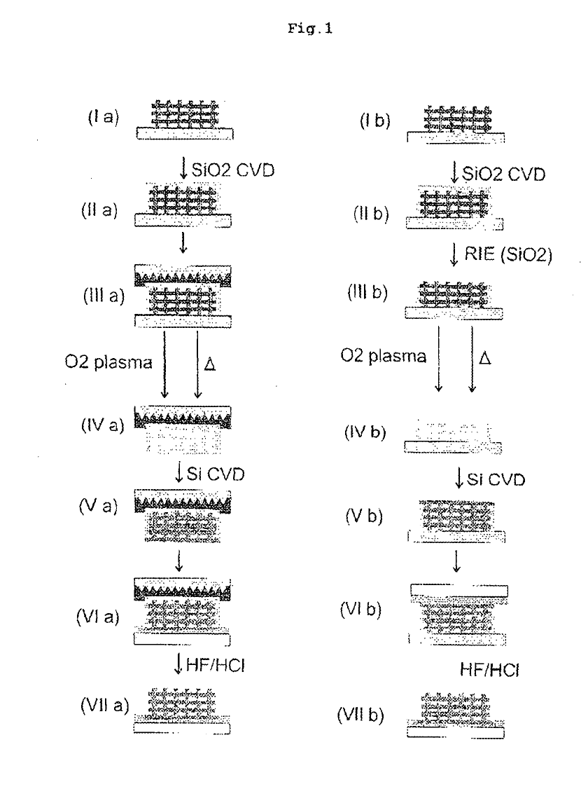

FIG. 1 Schematic illustration of the process steps for two embodiments of the process.

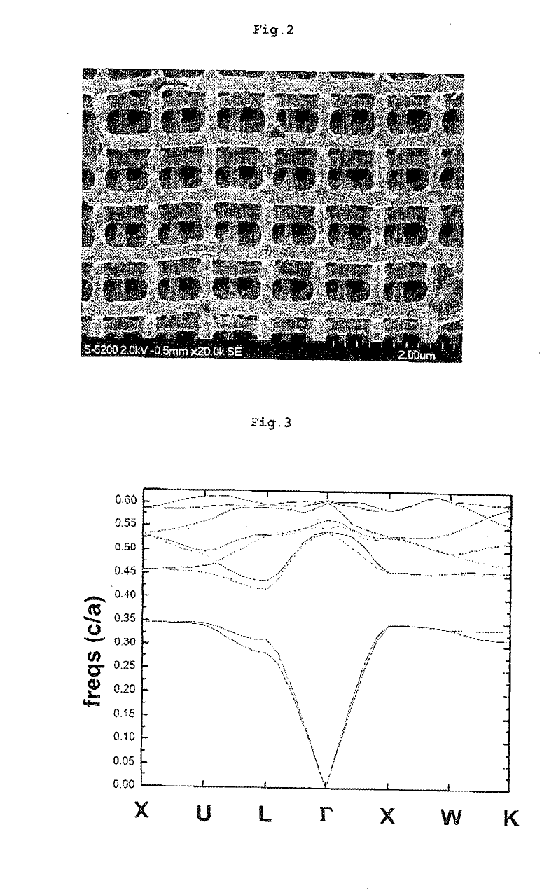

FIG. 2 Scanning electron micrograph of a double-inverted silicon structure.

FIG. 3 Calculated photonic band structure of a double-inverted silicon structure.

FIG. 1 shows a schematic of the process steps I-VII for two embodiments of the process designated by a and b:
Ia, Ib Starting point: substrate (glass) with applied polymeric photonic crystal, produced with multiphonon or holographic polymerization (process step a).
IIa, IIb Filling of the interstitial sites of the polymeric photonic crystal by means of CVD of SiO₂ (process step b).
IIIa Application of a further substrate to the surface of the crystal composed of polymer and SiO₂.
IIIb Removal of the excess SiO₂ by means of reactive ion etching (RIE).
IVa Removal of the original substrate and of the polymeric photonic crystal by means of heating (Δ) or O₂ plasma etching (process step c).
IVb Removal of the polymeric photonic crystal by means of heating (Δ) or O₂ plasma etching (process step c).
Va, Vb Layer-by-layer introduction of silicon or another material with high refractive index into the interstitial sites of the photonic structure inverted with SiO₂ (process step d).
VIa, VIb Application of a further substrate to the surface of the crystal composed of silicon and SiO₂. VIIa, VIIb Removal of the SiO₂ by wet-chemical etching in a strong acid (e.g. HF or HCl) leads to a photonic crystal composed of silicon or composed of another material with high refractive index, whose cavities (pores) are filled by the surrounding atmosphere (air) (process step e).

Depending on the number of layers introduced in steps (II) and (V), photonic crystals with different topologies can be produced.

To perform the process according to the invention, in process step a), the starting point provided in each case is a polymeric photonic crystal which has been introduced by means of direct laser writing into a photoresist composed of EPON SU-8 and had been applied to a glass substrate which had optionally been covered with photopolymerized EPON SU-8.

Subsequently, SiO₂ was introduced layer by layer into the polymeric photonic crystal by means of chemical vapor deposition (CVD), for example via the SiCl₄ precursor substance, until complete filling of the polymer structure had been achieved (process step b).

Thereafter, two alternative embodiments which comprise process step c) were performed:
(a) The sample was rotated and applied to a further substrate which serves for transfer. In this working example, a glass substrate with a rough surface was selected for this purpose. The adhesive used was, for example, a sol-gel mixture of SiO₂ (silicate) which had been produced with TMOS and a commercially available suspension of silicate colloid particles in water. Commercially available high-temperature-resistant adhesives have likewise been used successfully. The original glass substrate and the polymeric photonic crystal were removed by O₂ plasma etching over 20 hours or by thermal decomposition of the polymer at 450° C. over 6 hours. A combination of the two processes was likewise found to be advantageous.
In this embodiment, the first substrate should preferably point downward, in order to be removed by gravity owing to lack of adhesion as soon as the polymer has decomposed. Otherwise, there is a risk that the first substrate and the silicate-inverted structure sinter together at the high temperatures which occur, as a result of which later introduction of highly refractive material is no longer possible.
(b) The SiO₂ structure which had grown above the surface of the photonic crystal was removed by means of controlled reactive ion etching. The original polymeric photonic crystal was removed by O₂ plasma etching over 20 hours or by thermal decomposition of the polymer at 450° C. over 6 hours. A combination of the two processes was likewise found to be successful.

As a result, a mirror image of the original polymeric photonic crystal was obtained, which withstands the high temperatures which are required for the pyrolysis of the disilane (Si₂H₆) precursor substance during the layer by layer application of hydrogenated amorphous silicon (a-Si:H) during process step d) by chemical vapor deposition (CVD).

The pressure was kept constant at 320 Pa (2.4 Torr), while the coating rate and the optical properties of the film were laid down by the temperature of the substrate, which can vary between 340 and 430° C.

In order to obtain hydrogenated nanocrystalline silicon (nc-Si:H), the sample was then treated thermally in a nitrogen atmosphere with 5% hydrogen at 600° C. for 20 hours.

Subsequently, the sample was rotated and placed onto a polymethyl methacrylate (PMMA) substrate of high optical quality or another substrate which does not react in strong acids and which meets the optical requirements, onto which a thin adhering film of a photopolymerizable polymer of high optical quality has been applied. In order to achieve good adhesion, the sample was then placed under an ultraviolet lamp for 5-10 minutes.

Finally, in process step e), the silicate substrate and the photonic crystal were etched completely in a solution composed of 10% by weight of aqueous hydrogen fluoride (HF) and 12% by weight of aqueous hydrochloric acid (HCl).

FIG. 2 shows a scanning electron micrograph (SEM) of an inverted silicon woodpile structure produced in accordance with the invention in high magnification. It becomes clear that the replica has been completely inverted, has been distributed homogeneously over the entire volume of the original polymer structure and has a smooth surface.

To analyze the properties of the photonic crystals produced in accordance with the invention, band structure calculations were performed on the basis of the plane-wave expansion method.

To this end, the lattice was modeled as fixed rectangular silicon beams which are arranged in a classical woodpile structure against a background of air. A value of n=3.45 for the refractive index of nc-Si:H was used owing to the agreement of experimental findings in thin films on silicate with literature data.

The result of the calculations for this structure can be found in FIG. 3. This structure has a band gap of 23% (width of the band gap based on the center frequency) at a frequency of 2.6 μm. These band structure calculations prove the presence of a completely photonic band gap with a pronounced structure.

1. A process for producing a photonic crystal which consists of a material having high refractive index, comprising the following process steps:
a) providing a photonic crystal which consists of a polymer and through whose surface there are empty interstitial sites,
b) introducing a filler into the interstitial sites, so that a network of the filler is formed therein,
c) removing the polymer, which forms cavities in the network formed from the filler,
d) introducing a material with high refractive index into the cavities, so that a structure of the material with high refractive index is formed therein,
e) removing the filler, which leaves the structure of the material with high refractive index, which can be removed as the photonic crystal which consists of a material with high refractive index.

2. The process as claimed in claim 1, wherein the photonic crystal which consists of a polymer is applied to a first substrate.

3. The process as claimed in claim 1, wherein the photonic crystal which consists of a polymer is produced by means of holographic lithography or direct laser inscription.

4. The process as claimed in claim 2, wherein the photonic crystal which consists of a polymer is applied on a layer of the same polymer which covers the first substrate.

5. The process as claimed in claim 1, wherein a precursor substance of the filler is introduced into the photonic crystal which consists of a polymer up to a fill level which is selected such that the filler, after removal of the polymer, forms a network comprising cavities.

6. The process as claimed in claim 1 with silicate (SiO₂) as the filler.

7. The process as claimed in claim 6 with silicon tetrachloride (SiCl₄) as the precursor substance of the filler.

8. The process as claimed in claim 2, wherein, before the removal of the polymer, second substrate is applied to the surface of the photonic crystal which consists of a polymer after a network of the filler has formed in its interstitial sites.

9. The process as claimed in claim 8, wherein the second substrate is applied by means of a sol-gel process or an adhesive.

10. The process as claimed in claim 1, wherein the polymer is removed by means of plasma etching or thermal decomposition.

11. The process as claimed in claim 1, wherein the material with high refractive index is introduced layer by layer into the cavities.

12. The process as claimed in claim 1 with silicon, germanium or an alloy of the two semiconductors as the material with high refractive index.

13. The process as claimed in claim 12 with hydrogenated nanocrystalline silicon (nc-Si:H) as the material with high refractive index.

14. The process as claimed in claim 1, wherein, after the introduction of the material with high refractive index into the cavities, a third substrate which is resistant toward strong acids is applied with a visually transparent adhesive.

15. The process as claimed in claim 1 wherein the filler is removed by means of an acid.

16. The process as claimed in claim 15, wherein the filler is removed with a strong acid together with the first or the second substrate.
